(19) United States
(12) Patent Application Publication
(10) Pub. No.: US 2007/0061669 A1
(43) Pub. Date: Mar. 15, 2007

(54) Method, device and system for detecting error correction defects

(76) Inventors: Karl L. Major, Boise, ID (US); Wai-Leong Mook, Boise, ID (US)

Correspondence Address: TRASK BRITT, P.C./ MICRON TECHNOLOGY, P.O. BOX 2550, SALT LAKE CITY, UT, 84110, US

(21) Appl. No.: 11/214,696

(22) Filed: Aug. 30, 2005

(51) Int. Cl. H03M 13/00

(52) U.S. Cl. 714/758

(57) ABSTRACT

A method, device and system for detecting error correction defects calculates a written error checking and correction (ECC) code for a written data and writes the written data and the written ECC code into a plurality of memory cells. When data is read from the memory cells including data representing ECC code, any errors are identified in the data from the ECC code. When the quantity of errors exceeds the correctable quantity supported by the ECC code, then the data is output “as-is” without attempts to correct the data or fail the memory device if the memory device is under test.

### BACKGROUND OF THE INVENTION

1. Field of the Invention

The invention relates to memory devices and, more particularly, to a method and system for detecting defects in error correction circuitry.

2. State of the Art

Computers and other electronic systems rely on semiconductor memory devices to store data and instructions for processing by a controller. Generally, such systems include memory which frequently consists of dynamic random access memory (DRAM) devices. The storage cost per bit of information in DRAM devices is relatively low because a DRAM memory cell is formed using relatively few circuit components for storing a bit of information or data bit as compared with other types of memory cells, such as static random access memory (SRAM) devices. Thus, a high capacity system memory may be implemented using DRAM devices for a relatively low cost.

While DRAM devices may be advantageous from an economic perspective, DRAM devices include a disadvantage of significant power consumption. In fact, DRAM devices used in digital systems, such as computers, may consume a significant percentage of the total power consumed by the system. The power consumed by the memory devices may greatly effect the usability, namely, the usable duration of the system before power replenishment is required. Additionally, power consumption is also of importance for memory devices that are not powered by isolated sources such as batteries because many electronic systems as well as the reliability of such systems are affected by heat generated by the consumption of power in memory devices.

In memory devices, one operation that tends to consume power at a substantial rate is the refreshing of memory cells in a DRAM device. As is well known in the art, DRAM memory cells each essentially consists of a charge storage capacitor which must be periodically refreshed to retain stored charge of the information bit and a pass transistor which selectively isolates the storage capacitor from other circuit components. The refreshing of the charge stored within the storage capacitor must be performed on a periodic basis and is typically performed by activating each row of memory cells in a memory array. The activation of each row results in essentially a read of the data bits from the memory cells in each row and then internally rewrites those same data bits back into the same cells in the row. This refresh operation is generally performed at a rate needed to keep the charge stored in the memory cells from excessively leaking and thereby dissipating the usefulness of the stored information. The refresh operation of memory cells tends to be a particularly power-consumptive operation since refresh involves accessing data bits in a large number of memory cells at a rapid rate. Thus, many approaches have been conceived to reduce power consumption in DRAM devices through modifications to the power-consuming refresh operations.

One approach that has been devised to reduce the amount of power consumed in a computer is to decrease the refresh rate of DRAM memory cells. As is well known, to continuously hold data stored in memory cells of the DRAM device, refresh operations must be performed periodically. Because charge leaks from various memory cells at different rates due to fabrication variations, certain memory cells may prematurely bleed or lose charge sufficient to render indistinguishable the logic state of particular information stored within a memory cell. Reduction of the refresh rate of memory cells may result in at least a portion of the data becoming corrupted. Therefore, when data is retrieved from memory cells, the retrieved or read data does not always match the data as originally written to the memory cells. Such errors can be caused, as stated, by processing variations or a variety of other operating conditions such as power supply fluctuations, noise, etc.

Regardless of the source of errors, such errors are clearly undesirable. Consequently, many modern memory systems include error detection or checking and/or error correction capabilities. Typical approaches for detecting and correcting errors in memory devices rely upon some form of error correction code to identify and correct data errors. Such error correction codes typically include a mathematical algorithm that is applied to the data to be checked and corrected resulting in additional bits known herein as Error Checking and Correction (ECC) code or bits. Generally, the ECC code is stored in other memory cells within the same or a different memory device. The amount of memory dedicated for storing the ECC bits may be significant and can exceed ten to fifteen percent of the number of information data bits. The quantity of ECC code bits required can depend upon the type of error correction code being utilized. In some applications, very little or no correction is desired, however, other computer applications can tolerate little or no data errors.

Other applications of ECC code include the reconstruction of stored data wherein portions of the data become corrupted due to an attempt by system designers to reduce, stretch or delay the refresh operation of the memory cells. If the refresh operation of the memory cells is extended to a duration wherein the error correction capability of the memory device does not exceed the number of errors present, then overall conservation of power has been improved.

As stated, the overhead associated with supporting error checking and correction for reducing power consumption also results in the fabrication of an appreciable amount of additional overhead memory cells and other circuitry for processing and storing the ECC code. Such ECC code overhead circuitry is also susceptible to fabrication and manufacturing anomalies which contribute to failures of the memory device. Therefore, what is needed is a methodology for reducing the amount of memory devices that are failed during testing when the failure mode is attributable to failures located within the error checking and correction overhead logic.

### BRIEF SUMMARY OF THE INVENTION

The present invention, in exemplary embodiments, relates to a method, device and system for detecting error correction defects in a memory device. One embodiment comprises a method for operating a memory device, including calculating a written error checking and correction (ECC) code for a written data and writing the written data into the first plurality of memory cells and the written ECC code into a second plurality of memory cells. A read data and a read ECC code is read from the first and second plurality of memory cells and any errors between the read data and read ECC code are detected. When the quantity of errors exceeds a correctable quantity, the read data is output as the requested data.

In another embodiment of the present invention, a memory device is provided. The memory device includes a first and second plurality of memory cells configured to have respectively written thereto a written data and a written ECC code and read therefrom a read data and a read ECC code. The memory device further includes error checking and correction logic coupled to the first and second plurality of memory cells and configured to calculate the written ECC code for the written data and detect any errors between the read data and the read ECC code when compared with the written data and the written ECC code.

In a further embodiment of the present invention, an electronic system is provided. The electronic system includes an input device, an output device, a memory device, and a processor device coupled to the input, output, and memory devices. The memory device includes a first and second plurality of memory cells configured to have respectively written thereto a written data and a written ECC code and read therefrom a read data and a read ECC code. The memory device further includes error checking and correction logic coupled to the first and second plurality of memory cells and configured to calculate the written ECC code for the written data and detect any errors between the read data and the read ECC code when compared with the written data and the written ECC code.

In yet another embodiment of the present invention, an integrated circuit die is provided and includes a memory array including a first and second plurality of memory cells configured to have respectively written thereto a written data and written ECC code and read therefrom a read data and a read ECC code. The integrated circuit die further includes error checking and correction logic coupled to the first and second plurality of memory cells and configured to calculate the written ECC code for the written data and detect any errors between the read data and the read ECC code when compared with the written data and the written ECC code.

In yet a further embodiment of the present invention, a semiconductor wafer including an integrated circuit is provided. The integrated circuit includes a memory array including a first and second plurality of memory cells configured to have respectively written thereto a written data and written ECC code and read therefrom a read data and a read ECC code. The integrated circuit further includes an error checking and correction logic coupled to the first and second plurality of memory cells and configured to calculate the written ECC code for the written data and detect any errors between the read data and the read ECC code when compared with the written data and the written ECC code.

In yet a further embodiment of the present invention, a method for operating a memory device is provided. The method includes calculating a written ECC code for a written data and writing the written data into the first plurality of memory cells and the written ECC code into a second plurality of memory cells. The memory cells are refreshed and read data and read ECC code is read therefrom. Any errors are detected and when the errors exceed the detectable quantity, the read data is output as the requested data.

### BRIEF DESCRIPTION OF THE SEVERAL VIEWS OF THE DRAWINGS

In the drawings, which illustrate what is currently considered to be the best mode for carrying out the invention:

FIG. 1 is functional block diagram of a memory system including a memory controller and a memory device which further includes error checking and correction circuitry, in accordance with an embodiment of the present invention;

FIG. 2 is a block diagram of error checking and correction logic, in accordance with an embodiment of the present invention;

FIG. 3 is a logic circuit diagram of an error checking and correction logic, in accordance with an embodiment of the present invention;

FIG. 4 is flowchart for operating a memory device, in accordance with an embodiment of the present invention;

FIG. 5 is a flowchart for testing a memory device, in accordance with an embodiment of the present invention;

FIG. 6 is a functional block diagram illustrating an electronic system including a memory device having error checking and correction, in accordance with an embodiment of the present invention; and

FIG. 7 is a diagram illustrating a semiconductor wafer having a circuit thereon for error checking and correction, in accordance with an embodiment of the present invention.

### DETAILED DESCRIPTION OF THE INVENTION

Error Checking and Correction (ECC) methodologies have been incorporated into memory device to provide increased integrity of stored data upon retrieval and to accommodate processing variations in specific memory cells which store various information bits of a collective information byte or word. ECC approaches provide a method for correcting a subset of the overall data byte or word based upon error correction code coinciding with the information byte or word that was generated when the information byte or word was first written to the plurality of memory cells. If a subset of the of the overall information byte or word was misfortunately written into inferior memory cells where the stored information, stored in the form of an electrical charge, prematurely leaks to an indeterminate level, then ECC methodologies attempt to correct the subset of information bits at the time the information byte or word is retrieved for outputting from the plurality of memory cells.

Applying ECC techniques to a memory device may result in the conservation of power used by the memory device by enabling the refresh rate to be extended to a point where the weakest subset of memory cells may dissipate the stored charge of a subset of the memory cells but the information may be reconstructed based upon the stored ECC code. However, as with the addition of any circuitry on an integrated circuit, each additional memory cell and logic gate, provide an additional opportunity for a fabrication defect that contributes to the failure and scrapping of a memory device. The incorporation of ECC techniques, while extending the yield of memory devices by providing a means for accommodating memory devices with a subset of leaky or inferior memory cells, also contributes to failures in memory devices.

For example, when an ECC methodology is utilized, the error checking and correction code is typically coded as well. Specifically, when an information byte or word is received in a memory device incorporating an ECC methodology, the entire aggregate of information bits (e.g., data bits and the ECC code) is coded for detection and correction. Such coding of the error correction code as well as the data prevents errors in the error correction code from improperly altering data bits when the error occurred in the retention of the error correction code.

Therefore, since an error in the retention of the error correction code would contribute to the inappropriate failure of a memory device, the memory device would be inaccurately characterized as a failed device when, in fact, only the ECC circuitry was defective and the device, if the ECC circuitry would not have been implemented on the device, would have been characterized as a functional device.

It is appreciated that ECC methodologies are characterized by the limitations of the quantity of errors that may be checked or detected and the quantity of errors that may be corrected. According to the various embodiments of the present invention, a memory device incorporates techniques that further incorporate error checking and correction such that when the ability of the specific error correction is exceeded, the error checking and correction circuitry is bypassed and the information byte or word is output in an “as-is” condition as retrieved from the corresponding memory cells. If the only failures within the memory device are related to the error correction code and the defective retention or outputting thereof, then the memory device will pass the functionality testing and be considered a function memory device. Thus, the manufacturing yield of memory devices is not impacted by faulty error checking and correction circuitry. Additionally, in an operational deployment of a functional memory device, when the memory device bypasses any error detection when the capability of error correction is exceeded, the memory device will also continue to function normally.

The various embodiments of the present invention appreciate that some memory devices are failed during testing because of defective memory cells or circuitry associated with the error checking and correction logic. On a one-by-one information byte, word basis or bit level, when the ability of the ECC methodology for correcting the information byte or word has been exceeded, the ECC capability is bypassed and the data, in an “as-is” condition, is output.

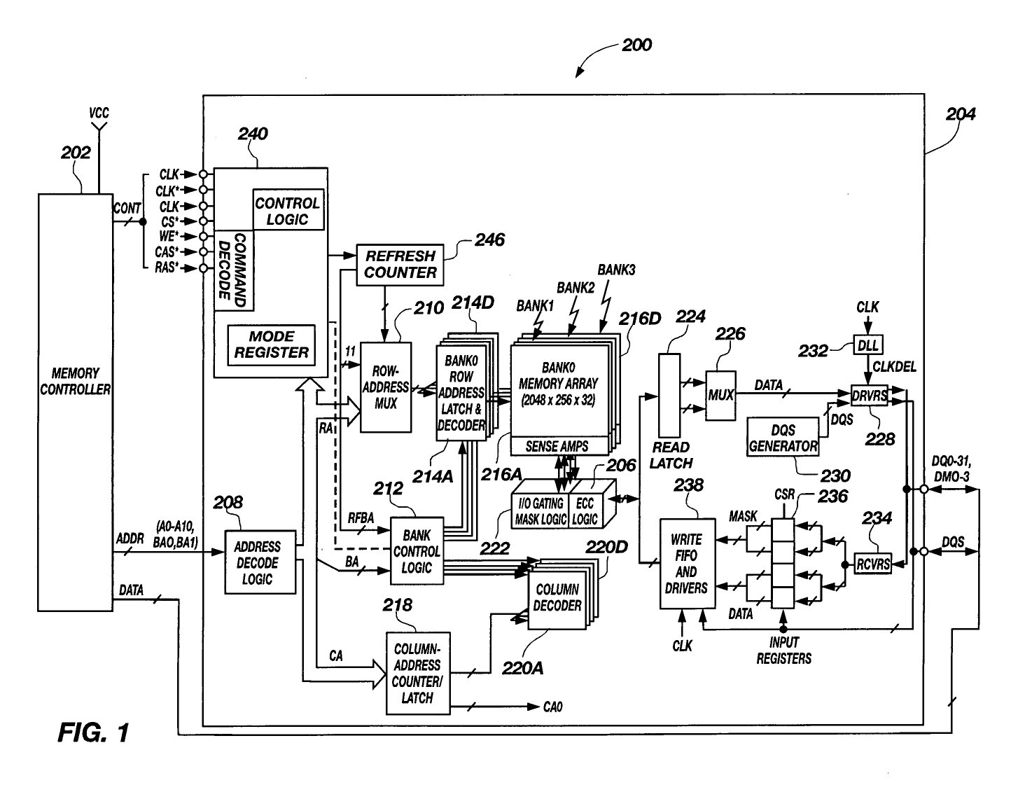

FIG. 1 is a functional block diagram of a memory system 200 including a memory controller 202 coupled to a memory device 204 that includes error checking and correction (ECC) logic 206, in accordance with various embodiments of the present invention. In operation, the ECC logic 206 generates error checking and correction code for information data, such as a byte or word, written to the memory. Additionally, the ECC logic 206 evaluates the information data read from the memory in view of the associated ECC code previously stored in conjunction with the storing of the information data within the memory device. Furthermore, the ECC logic 206 is further configured to correct errors in the information data prior to outputting the information data from the memory device when the quantity of errors does exceed a correctable quantity. When the quantity of errors exceeds the correctable quantity, the ECC logic 206 bypasses any attempted correction or alteration of the information data and directly outputs the information data in an “as-is” condition.

By way of example and not limitation, the memory device 204 in FIG. 1 may be a double-data rate (DDR) synchronous dynamic random access memory (“SDRAM”), although the principles described herein are applicable to any memory device containing memory cells that must be refreshed (i.e., that store dynamic data), such as conventional DRAMs and SDRAMs, as well as packetized memory device like synchronous link DRAM (“SLDRAM”) and Rambus DRAM (“RDRAM”), and are equally applicable to any integrated circuits that store dynamic data. In the following description, certain details are set forth to provide a sufficient understanding of the invention. It will be clear to one of ordinary skill in the art, however, that the invention may be practiced without these particular details. In other instances, well-known circuits, control signals, timing protocols, and software operations have not been shown in detail or omitted entirely in order to avoid unnecessarily obscuring the invention.

Before describing the ECC logic 206 in more detail, the various components of the memory device 204 will first be described. The memory controller 202 applies row, column, and bank addresses to an address register 208 over an address bus ADDR. Typically, a row address RA and a bank address BA are initially received by the address register 208 and applied to a row address multiplexer 208 and bank control logic circuit 210, respectively. The row address multiplexer 208 applies either the row address RA received from the address register 208 or a refresh row address RFRA received from the self-refresh counter 246 to a plurality of row address latch and decoder circuits 214A-D. The bank control logic 212 activates the row address latch and decoder circuit 214A-D corresponding to either the received bank address BA or a refresh bank address RFBA from the self-refresh counter 246, and the activated row address latch and decoder circuit latches and decodes the received row address.

In response to the decoded row address, the activated row address latch and decoder 214A-D applies various signals to a corresponding memory bank or array 216A-D to activate a row of memory cells corresponding to the decoded row address. The data in the memory cells in the accessed row is stored in sense amplifiers coupled to the array 216A-D, which also-refreshes the accessed memory cells as previously described. The row address multiplexer 210 applies the refresh row address RFRA to the row address latch and decoders 214A-D and the bank control logic circuit 212 uses the refresh bank address RFBA when the memory device 204 operates in an auto-refresh or self-refresh mode of operation in response to the controller 202 applying an auto- or self-refresh command to the memory device 204.

After the address register 208 via memory controller 202 has applied the row and bank addresses RA, BA, the memory controller applies a column address CA on the address bus ADDR. The address register 208 provides the column address CA to a column address counter and latch circuit 218 which, in turn, latches the column address and applies the latched column address to a plurality of column decoders 220A-D. The bank control logic 212 activates the column decoder 220A-D corresponding to the received bank address BA, and the activated column decoder decodes the column address CA from the counter and latch circuit 218.

Depending on the operating mode of the memory device 204, the counter and latch circuit 218 either directly applies the latched column address to the decoders 220A-D, or applies a sequence of column addresses to the decoders starting at the column address CA provided by the address register 208. In response to the column address from the counter and latch circuit 218, the activated column decoder 222A-D applies decode and control signals to an I/O gating and data masking circuit 222 which, in turn, accesses memory cells corresponding to the decoded column address in the activated row of memory cells in the array 216A-D being accessed.

During data read operations, data being read from the activated array 216A-D is coupled through the I/O gating and data masking circuit 222 to a read latch 224. The circuit 222 supplies N bits of data to the read latch 224, which then applies two N/2 bit words to a multiplexer 226. In a specific embodiment, the circuit 222 may provide 64 bits to the read latch 224 which, in turn, provides two 32 bits words to the multiplexer 226. A data driver circuit. 228 sequentially receives the N/2 bit words from the multiplexer 226 and also receives a data strobe signal DQS from a strobe signal generator 230 and a delayed clock signal CLKDEL from a delay-locked loop (DLL) circuit 232. The DQS signal has the same frequency as the CLK, CLK* signals, and is used by the controller 202 in latching data from the memory device 204 during read operations.

In response to the delayed clock signal CLKDEL, the data driver circuit 228 sequentially outputs the received N/2 bit words as corresponding data words DQ that are in synchronism with rising and falling edges of the CLK signal, respectively, and also outputs the data strobe signal DQS having rising and falling edges in synchronism with rising and falling edges of the CLK signal, respectively. Each data word DQ and the data strobe signal DQS collectively define a data bus DATA coupled to the controller 202 which, during read operations, latches the each N/2 bit DQ word on the DATA bus responsive to the data strobe signal DQS. As will be appreciated by those of ordinary skill in the art, the CLKDEL signal is a delayed version of the CLK signal, and the DLL circuit 232 adjusts the delay of the CLKDEL signal relative to the CLK signal to ensure that the DQS signal and the DQ words are placed on the DATA bus in synchronism with the CLK signal. The DATA bus also includes masking signals DQM0-X, which will be described in more detail below with reference to data write operations.

During data write operations, the memory controller 202 applies N/2 bit data words DQ, the strobe signal DQS, and corresponding data masking signals DM0-X on the data bus DATA. A data receiver circuit 234 receives each DQ word and the associated DM0-X signals, and applies these to an input register 236 that is clocked by the DQS signal. In response to a rising edge of the DQS signal, the input register 236 latches a first N/2 bit DQ word and the associated DM0-X signals, and in response to a falling edge of the DQS signal the input register latches the corresponding N/2 bit DQ word and associated DM0-X signals. The input register 236 provides the two latched N/2 bit DQ words as an N-bit word to a write FIFO and driver circuit 238, which clocks the applied DQ word and DM0-X signals into the write FIFO and driver circuit in response to the DQS signal. The DQ word is clocked out of the write FIFO and driver circuit 238 in response to the CLK signal, and is applied to the I/O gating and masking circuit 222. The I/O gating and masking circuit 222 transfers the DQ word to the accessed memory cells in the activated array 216A-D subject to the DM0-X signals, which may be used to selectively mask bits or groups of bits in the DQ words (i.e., in the write data) being written to the accessed memory cells.

A control logic and command decoder circuit 240 receives a plurality of command and clocking signals from the memory controller 202 over a control bus CONT, and generates a plurality of control and timing signals to control the components 206-238 during operation of the memory device 204. The command signals include a chip select signal CS*, a write enable signal WE*, a column address strobe signal CAS*, and a row address strobe signal RAS*, while the clocking signals include a clock enable signal CKE* and complementary clock signals CLK, CLK*, with the “*” designating a signal as being active low. The memory controller 202 drives the command signals CS*, WE*, CAS*, and RAS* to values corresponding to a particular command, such as a read, write, auto-refresh, and standby-like commands such as self-refresh and power-down commands.

In response to the clock signals CLK, CLK*, the command decoder circuit 240 latches and decodes an applied command, and generates a sequence of control signals, including power reduction control signal 300, that control various components in the memory device to execute the function of the applied command. The clock enable signal CKE enables clocking of the command decoder circuit 240 by the clock signals CLK, CLK*. The command decoder circuit 240 latches command and address signals at positive edges of the CLK, CLK* signals (i.e., the crossing point of CLK going high and CLK* going low), while the input registers 236 and data drivers 228 transfer data into and from, respectively, the memory device 204 in response to both edges of the data strobe signal DQS− and thus at double the frequency of the strobe signal and clock signals CLK, CLK*. For this reason the memory device 204 is referred to as a double-data-rate device, with data being transferred to and from the device at double the rate of a conventional SDRAM, which transfers data at a rate corresponding to the frequency of the applied clock signal. The detailed operation of the control logic of the command decoder circuit 240 in generating the control and timing signals is conventional, and thus, for the sake of brevity, will not be described in more detail.

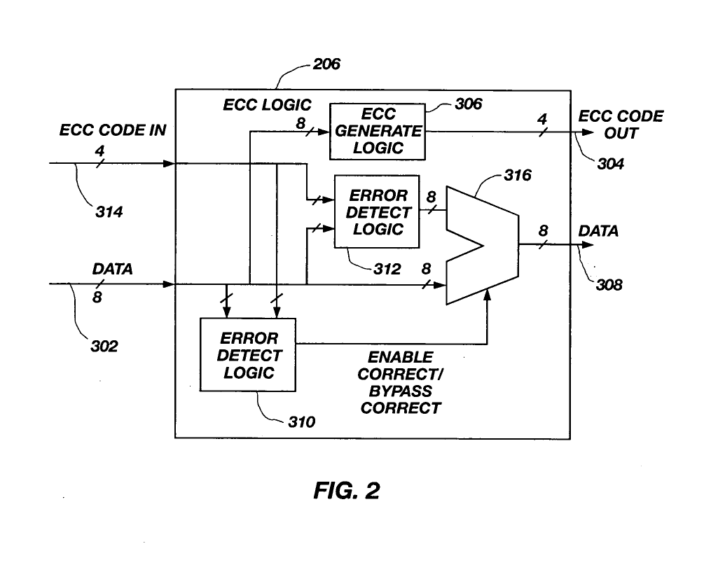

FIG. 2 is a block diagram of ECC logic, in accordance with an embodiment of the present invention. The ECC logic 206 receives data 302 from write FIFO and drivers 238 (FIG. 1) during a write operation to store data 302 and forthcoming ECC code 304 in a plurality of memory cells in the memory array. The ECC code 304 is generated when data 302 is passed through ECC generate logic 306. By way of example and not limitation, ECC generate logic is configured to utilize a coding structure, an example of which is a Hamming code methodology. An exemplary Hamming code methodology is configured to read in an 8-bit byte of information data and generate 4-bits of ECC code corresponding to an overall 12-bits of data and code. Once generated, the ECC code 304 accompanies the data 308 to be stored in memory cells until the data is read for outputting from the memory device.

ECC logic 206 further includes error detection logic 310 and error correction logic 312 utilized during a read operation when data is requested to be output from the memory device. Error detection logic 310 receives both data 302 and ECC code 314 as stored in the corresponding memory cells within the memory array and determines a quantity of errors therein in response to the logic states of the ECC code 314.

Error correct logic 312 also receives both data 302 and ECC code 314 and attempts to reconcile any logic level errors of the data 302. If the quantity of errors is too great for correction of the errors, the error detect logic 310 controls a selector 316 for bypassing outputting the uncorrectable data from the error correct logic 312 and data 302 through as the output data 308. In a deployed application, data 308 generally will contain correct data unless latent errors have occurred in the memory device. If the defects in the memory device are actual defects in the memory cells that store the information data, then the memory device would fail data integrity testing during the functional testing of the memory device following manufacture. If the defects are strictly related to the memory cells for holding the ECC code or other ECC related circuitry, bypassing the application of any ECC functionality will not modify the integrity of the data and therefore, the logical states of the data that was originally written to the memory cells will remain logically sound when read from the memory cells in anticipation of outputting the data.

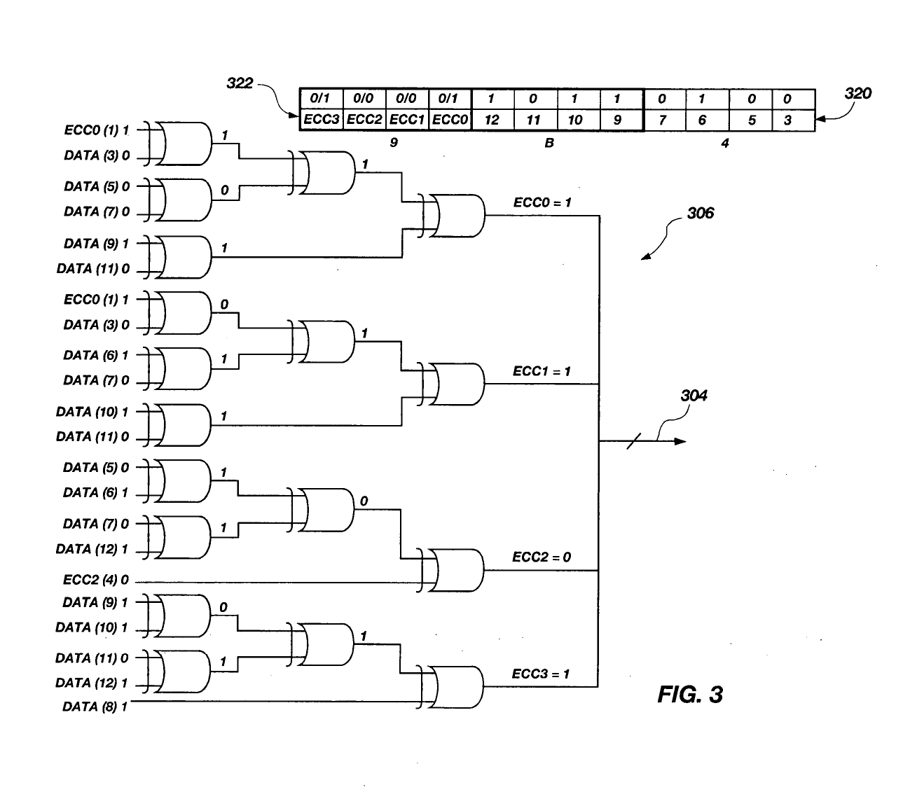

FIG. 3 is a circuit diagram of ECC generation logic 306, in accordance with an embodiment of the present invention. ECC generation logic 306 may be implemented using logic gates to minimize the impact to access times of the memory device. The ECC generation logic 306 is illustrated, by a specific example, wherein an input byte of data 320 includes a binary representation of the hexadecimal value “B4” as understood by those of ordinary skill in the art. When ECC code is generated, the ECC code values 322, ECC0-ECC3, are set to the “0” value. With the other values set, the resulting ECC code 304 becomes hexadecimal value “9” (ECC<3>=0, ECC<2>=1, ECC<1>=0, ECC<0>=1) for the data having a hexadecimal value “B4”.

While the present implementation is drawn to logic gates configured as EX-OR gates, other logic gates may be configured to obtain the same logical signals. Furthermore, executable configurations for generating the ECC code 304 are also contemplated to be within the scope of the present invention.

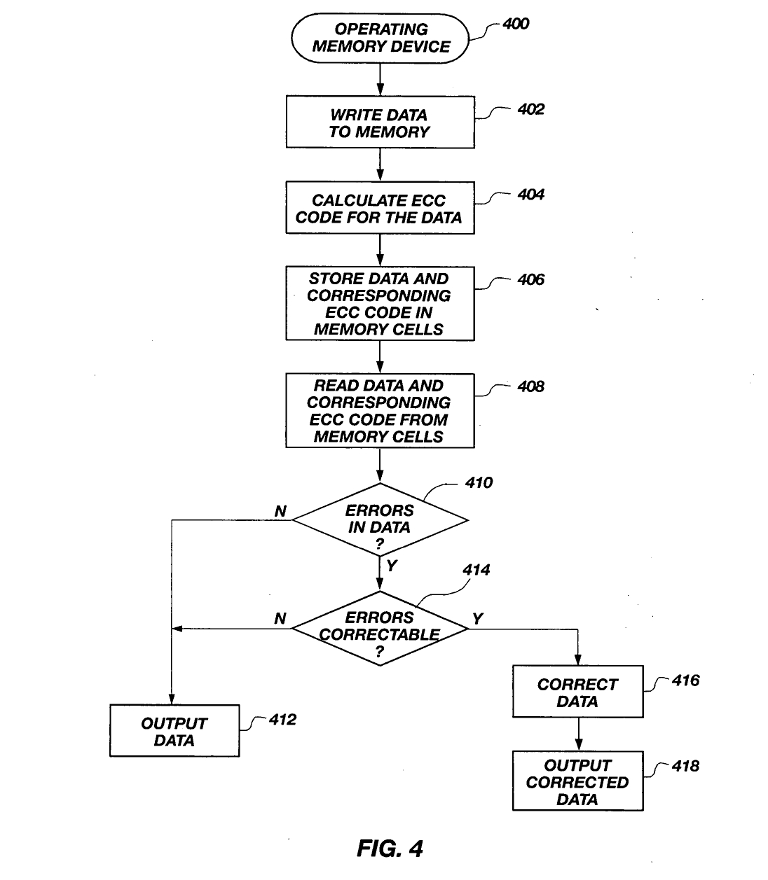

FIG. 4 is a flowchart of a method for operating a memory device, in accordance with an embodiment of the present invention. A memory device operation method 400 includes operation of a memory device that has been previously functionally tested and is deployed in a system. The operation method includes writing 402 to the memory device for storage therein. Since the memory device employs error checking and correction methodologies, an ECC code is calculated 404 using one or more approaches. By way of example and not limitation, a Hamming code may be employed which may be configured to evaluate the bit pattern of an 8-bit data byte and generate a 4-bit ECC code. The ECC code may be generated from logic circuitry that calculates the ECC code from a lookup table that has stores combinations corresponding to the desired bit pattern.

As stated, once an ECC code has been calculated or generated, the data and the ECC code are respectively stored 406 or written into a first plurality of memory cells and a second plurality of memory cells. The data and ECC code are retained in the memory cells through charge maintenance techniques such as memory cell refresh techniques, the specifics of which are not further described herein. When desired, either through operation programming or manufacturing testing, the data and the ECC code are read 408 or retrieved from the respective plurality of memory cells. Once retrieved, the ECC code is evaluated to determine 410 if errors in the data have occurred. If errors have not occurred in the data, then the data is output 412 as requested. If errors are present, then a determination 414 is performed to evaluate the correctability of the errors. If the errors are not correctable, meaning the exceed ECC logic limits, then the data as presently existing are output 412 in an “as-is” condition. If the errors are correctable, then the erroneous data is corrected 416 and then the corrected data is outputted 418 as requested.

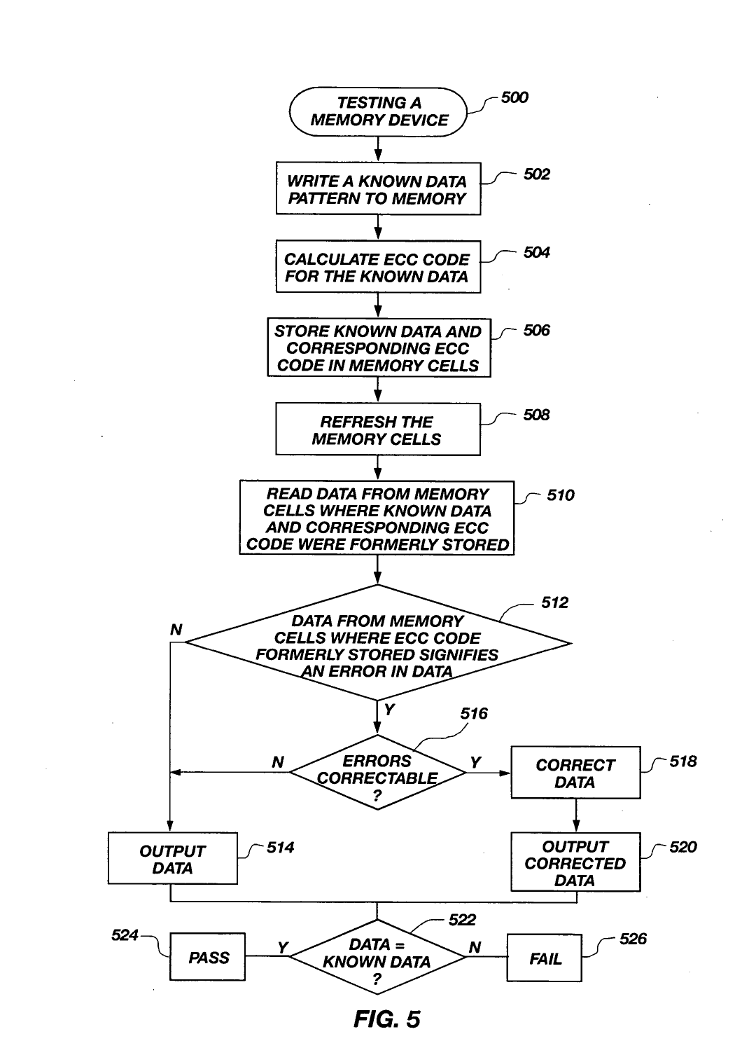

FIG. 5 is a flowchart of a method for testing a memory device, in accordance with an embodiment of the present invention. A memory device testing method 500 includes functional testing of a memory device that has been previously manufactured and is awaiting evaluation as to its functionality for inclusion in an electronic system. The testing method includes writing 502 a known test pattern into the memory device for storage therein. Since the memory device employs error checking and correction methodologies, an ECC code for the known test pattern is calculated 504 using one or more approaches. By way of example and not limitation, a Hamming code may be employed which may be configured to evaluate the known test bit pattern of, for example, an 8-bit data byte and generate a 4-bit ECC code. The ECC code may be generated from logic circuitry that calculates the ECC code from a lookup table or circuit that has store combinations corresponding to the known bit pattern.

Once an ECC code has been calculated or generated, the known test data and the ECC code are respectively stored 506 or written into a first plurality of memory cells and a second plurality of memory cells. The known test data and ECC code are retained in the memory cells through charge maintenance techniques such as memory cell refresh techniques for at least one refresh cycle 508, the specifics of memory cell refresh are not further described herein. The testing procedure then reads 510 or retrieves data from the memory cells wherein the known test pattern and the corresponding ECC code were stored. Once retrieved, the ECC code is evaluated to determine 512 if errors in the data have occurred. If errors have not occurred in the data, then the data is output 514. If errors are present, then a determination 516 is performed to evaluate the correctability of the errors. If the errors are not correctable, then the data as presently existing is output 514 in an “as-is” condition. If the errors are correctable, then the erroneous data is corrected 518 and then the corrected data is outputted 520. The test method then compares 522 the output data with the known test data and selects the memory device as a passing device 524 or a failed memory device 526.

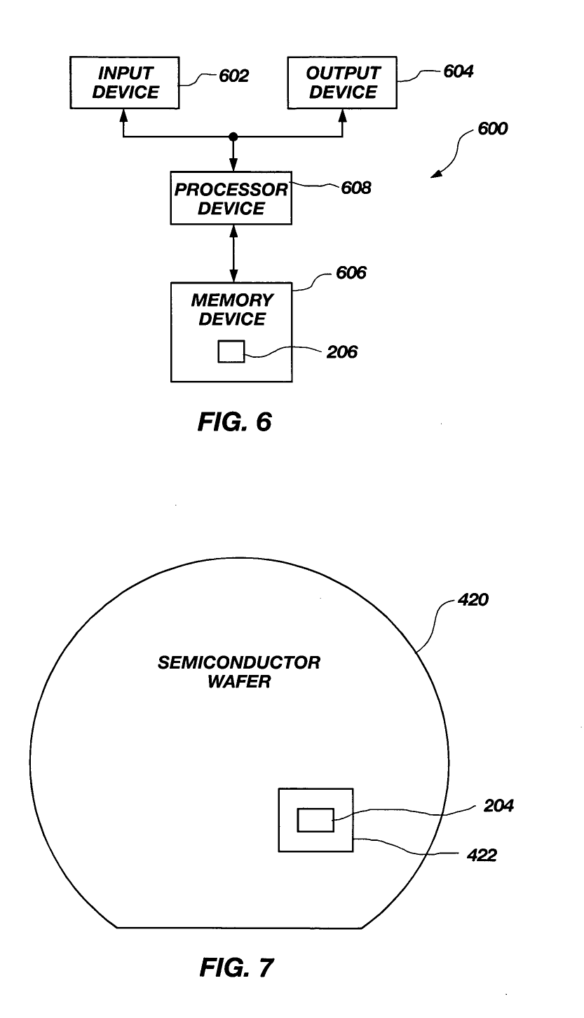

As shown in FIG. 6, an electronic system 400 includes an input device 402, an output device 404 and a memory device 406 all coupled to a processor device 408. Memory device 406 further includes the error checking and correction logic 206 as described herein above.

As shown in FIG. 7, a semiconductor wafer 420 includes a yet-to-be cut integrated circuit die 422 that incorporates the memory device 204 (FIG. 1) thereon.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention includes all modifications, equivalents, and alternatives falling within the spirit and scope of the invention as defined by the following appended claims.

1. A method for operating a memory device, comprising:
calculating a written error checking and correction (ECC) code for a written data;
writing the written data into the first plurality of memory cells and the written ECC code into a second plurality of memory cells;
reading from the first plurality of memory cells a read data and from the second plurality of memory cells a read ECC code;
detecting any errors between the read data and the read ECC code when compared with the written data and the written ECC code; and
outputting the read data when the errors exceed a correctable quantity.

2. The method of claim 1, further comprising configuring the written ECC code to include a Hamming code of the written data.

3. The method of claim 1, further comprising configuring the written ECC code to detect two errors and to correct one error in the read data and the read ECC code.

4. The method of claim 1, wherein outputting the read data further comprises comparing the read data with the written data.

5. The method of claim 4, wherein outputting the read data further comprises accepting as operable the memory device when the read data matches the written data.

6. The method of claim 1, wherein outputting comprises outputting corrected data matching the written data in response to the read ECC code when the errors do not exceed the correctable quantity.

7. The method of claim 1, further comprising refreshing the first and second plurality of memory cells.

8. A memory device, comprising:
a first and second plurality of memory cells configured to have respectively written thereto a written data and a written error checking and correction (ECC) code and read therefrom a read data and a read ECC code; and
error checking and correction logic coupled to the first and second plurality of memory cells and configured to calculate the written ECC code for the written data and detect any errors between the read data and the read ECC code when compared with the written data and the written ECC code.

9. The memory device of claim 8, wherein the error checking and correction logic is further configured to calculate the written ECC code as a Hamming code of the written data.

10. The memory device of claim 8, wherein the error checking and correction logic is further configured to detect two errors and to correct one error in the read data and the read ECC code.

11. The memory device of claim 8, wherein the error checking and correction logic is further configured to output corrected data matching the written data in response to the read ECC code when the errors do not exceed the correctable quantity.

12. The memory device of claim 8, further comprising refresh logic configured to refresh the first and second plurality of memory cells.

13. An electronic system including an input device, an output device, a memory device, and a processor device coupled to the input, output, and memory devices, the memory device comprising:
a first and second plurality of memory cells configured to have respectively written thereto a written data and a written error checking and correction (ECC) code and read therefrom a read data and a read ECC code; and
error checking and correction logic coupled to the first and second plurality of memory cells and configured to calculate the written ECC code for the written data and detect any errors between the read data and the read ECC code when compared with the written data and the written ECC code.

14. The electronic system of claim 13, wherein the error checking and correction logic is further configured to calculate the written ECC code as a Hamming code of the written data.

15. The electronic system of claim 13, wherein the error checking and correction logic is further configured to detect two errors and to correct one error in the read data and the read ECC code.

16. The electronic system of claim 13, wherein the error checking and correction logic is further configured to output corrected data matching the written data in response to the read ECC code when the errors do not exceed the correctable quantity.

17. The electronic system of claim 13, further comprising refresh logic configured to refresh the first and second plurality of memory cells.

18. An integrated circuit die, comprising:
a memory array including a first and second plurality of memory cells configured to have respectively written thereto a written data and a written error checking and correction (ECC) code and read therefrom a read data and a read ECC code; and
error checking and correction logic coupled to the first and second plurality of memory cells and configured to calculate the written ECC code for the written data and detect any errors between the read data and the read ECC code when compared with the written data and the written ECC code.

19. The integrated circuit die of claim 18, wherein the error checking and correction logic is further configured to calculate the written ECC code as a Hamming code of the written data.

20. The integrated circuit die of claim 18, wherein the error checking and correction logic is further configured to detect two errors and to correct one error in the read data and the read ECC code.

21. The integrated circuit die of claim 18, wherein the error checking and correction logic is further configured to output corrected data matching the written data in response to the read ECC code when the errors do not exceed the correctable quantity.

22. The integrated circuit die of claim 18, further comprising refresh logic configured to refresh the first and second plurality of memory cells.

23. A semiconductor wafer including an integrated circuit, comprising:
a memory array including a first and second plurality of memory cells configured to have respectively written thereto a written data and a written error checking and correction (ECC) code and read therefrom a read data and a read ECC code; and
error checking and correction logic coupled to the first and second plurality of memory cells and configured to calculate the written ECC code for the written data and detect any errors between the read data and the read ECC code when compared with the written data and the written ECC code.

24. The semiconductor wafer of claim 23, wherein the error checking and correction logic is further configured to calculate the written ECC code as a Hamming code of the written data.

25. The semiconductor wafer of claim 23, wherein the error checking and correction logic is further configured to detect two errors and to correct one error in the read data and the read ECC code.

26. The semiconductor wafer of claim 23, wherein the error checking and correction logic is further configured to output corrected data matching the written data in response to the read ECC code when the errors do not exceed the correctable quantity.

27. The semiconductor wafer of claim 23, further comprising refresh logic configured to refresh the first and second plurality of memory cells.

28. A method of operating a memory device, comprising:
calculating a written error checking and correction (ECC) code for a written data;
writing the written data into the first plurality of memory cells and the written ECC code into a second plurality of memory cells;
refreshing the first and second plurality of memory cells;
reading from the first plurality of memory cells a read data and from the second plurality of memory cells a read ECC code;
detecting any errors between the read data and the read ECC code when compared with the written data and the written ECC code; and
outputting the read data when the errors exceed a correctable quantity.

29. The method of claim 28, wherein the written ECC code includes a Hamming code of the written data.

30. The method of claim 28, wherein the written ECC code is configured to detect two errors and to correct one error in the read data and the read ECC code.

31. The method of claim 28, wherein outputting comprises outputting corrected data matching the written data in response to the read ECC code when the errors do not exceed the correctable quantity.
